(19) United States
(12) Patent Application Publication
(10) Pub. No.: US 2024/0224740 A1
(43) Pub. Date: Jul. 4, 2024

(54) FLEXIBLE DISPLAY DEVICE

(71) Applicant: LG Display Co., Ltd., Seoul (KR)

(72) Inventor: SungGyu KIM, Paju-si (KR)

(73) Assignee: LG Display Co., Ltd., Seoul (KR)

(21) Appl. No.: 18/384,488

(22) Filed: Oct. 27, 2023

(30) Foreign Application Priority Data
Dec. 28, 2022 (KR) 10-2022-0188031

(51) Int. Cl. H10K 59/80; H10K 59/123; H10K 77/10

(52) U.S. Cl. CPC H10K 59/878; H10K 59/123; H10K 59/8722; H10K 77/111

(57) ABSTRACT

A flexible display device can include a display panel including an active area and a non-active area where the non-active area includes a bending area, a plurality of light emitting elements disposed in the active area of the display panel, a plurality of conductive lines disposed in the non-active area of the display panel and extending to the active area, and a reflective layer disposed under the plurality of conductive lines in the non-active area between the active area and the bending area, so that the flexible display device provides an effect of preventing assembly defects due to leakage of uncured resin.

### CROSS-REFERENCE TO RELATED APPLICATIONS

This application claims priority under 35 U.S.C. § 119(a) to Korean Patent Application No. 10-2022-0188031 filed in the Republic of Korea on Dec. 28, 2022, the entire contents of which are hereby expressly incorporated by reference into the present application.

### BACKGROUND

### Technical Field

The present disclosure relates to a flexible display device and more particularly, to a flexible display device allowing for a reduction in a width of a bezel.

### Description of the Related Art

Recently, as society advances toward an information-oriented society, the field of display devices for visually expressing electrical information (e.g., via electrical signals) has rapidly advanced. Various display devices, having excellent performance in terms of thinness, weight reduction, and low power consumption, are being developed correspondingly.

Representative display devices can include a liquid crystal display device (LCD), a field emission display device (FED), an electro-wetting display device (EWD), an organic light emitting display device (OLED), and the like.

An electroluminescent display device represented by an organic light emitting display device is a self-light emitting display device, and can be manufactured to be light and thin since it does not require a separate light source, unlike a liquid crystal display device having a separate light source. Electroluminescent display devices (ELDs) are a type of flat panel display created by sandwiching a layer of electroluminescent material such as Gallium Arsenide (GaAs) between two layers of conductors, and include AC-driven ELDs and DC-driven ELDs. In addition, the electroluminescent display device has advantages in terms of power consumption (e.g., they are energy efficient) due to a low voltage driving, and is excellent in terms of a color implementation, a response speed, a viewing angle, and a contrast ratio (CR), are lightweight and thin. Therefore, electroluminescent display devices are expected to be utilized in various fields, such as video displays, alphanumeric displays, instrument panels, nightlights, clocks, toys, etc.

In the electroluminescent display device, an emissive layer (EML) is disposed between two electrodes formed of an anode and a cathode. When holes from the anode are injected into the emissive layer and electrons from the cathode are injected into the emissive layer, the injected electrons and holes recombine with each other to form excitons in the emissive layer and emit light.

A host material and a dopant material (e.g., manganese, copper, silver, terbium, europium and the like) are included in the emissive layer and interact with each other. A host generates excitons from the electrons and holes and transfers energy to a dopant. The dopant is a dye-based organic material that is added in a small amount, and receives the energy from the host to convert it into light.

The electroluminescent display device is encapsulated with glass, metal, or film to block the introduction of moisture or oxygen from the outside to the interior of the electroluminescent display device, thereby preventing oxidation of the emissive layer or the electrode and protecting it from external mechanical or physical impacts.

As display devices are miniaturized, efforts aimed at reducing a bezel area which is an outer portion of an active area, in order to increase a size of an effective display screen in the same area of the display device, are being continuously conducted.

However, since lines (e.g., conductive lines) and a driving circuit for driving the screen are disposed in the bezel area corresponding to a non-active area, there can be a limitation in reducing the bezel area.

Recently, with regard to a flexible electroluminescent display device capable of maintaining a display performance even when bent, by applying a flexible substrate formed of a flexible material, such as a plastic material, there is an effort to reduce a bezel area by bending a non-active area of the flexible substrate, while securing an area for conductive lines and a driving circuit.

### SUMMARY OF THE DISCLOSURE

Electroluminescent display devices using a flexible substrate, such as plastic or the like, need to secure (e.g., maintain) flexibility of various insulating layers disposed on the substrate and conductive lines formed of a metal material and to prevent defects, such as cracks that can be caused by bending.

A protective layer, such as a micro-coating layer is disposed over (e.g., disposed on) the insulating layers and lines in a bending area to prevent the occurrence of cracks and protect the lines from an external foreign material. The protective layer can be coated to have a predetermined thickness and serve to adjust a neutral plane of the bending area.

In the recent electroluminescent display devices for minimizing the bezel area and allowing for a reduction in thickness of the display device, a bending area of a flexible substrate has an extreme curvature and a thickness of the micro-coating layer is minimized.

In addition, in order to reduce the bezel area, an outer frame of a flexible display device is formed using ultraviolet (UV) light curing or heat curing resin instead of a metal frame according to the related art. However, when the resin is cured using UV light, the resin can permeate into the flexible display device that is bent and thus can not be cured. Also, signal lines pass through the bezel area, and curing of the resin permeated into the flexible display device can be hindered by these signal lines.

Accordingly, the inventor of the present disclosure has recognized defects and limitations described above and conducted various experiments to cure resin uniformly and completely for inner sealing and outer sealing in the bending area. Through various experiments, the inventor has invented a new flexible display device capable of uniformly and completely curing an inner sealing part and an outer sealing part in a bending area.

An object to be solved or addressed according to one or more embodiments of the present disclosure is to provide a flexible display device capable of forming an outer frame with an outer sealing part without defects.

Objects of the present disclosure are not limited to the above-mentioned objects, and other objects, which are not mentioned above, can be clearly understood by those skilled in the art from the following descriptions.

A flexible display device according to an embodiment of the present disclosure includes a display panel including an active area and a non-active area, the non-active area including a bending area, a plurality of light emitting elements disposed in the active area of the display panel, a plurality of lines disposed in the non-active area of the display panel and extending to the active area and a reflective layer disposed under the plurality of lines in the non-active area between the active area and the bending area.

Other detailed matters of the embodiments are included in the detailed description and the drawings.

A flexible display device according to an embodiment of the present disclosure can provide effects of improving an aesthetic sense by reducing a width of a bezel.

A flexible display device according to the embodiment of the present disclosure provides an effect of preventing assembly defects due to leakage of uncured resin by uniformly and completely curing the inner and outer sealing parts in the bending area.

A flexible display device according to the embodiment of the present disclosure provides an effect of preventing assembly defects due to a difference in curing of an inner sealing part and an outer sealing part in a bending area without an additional process.

The effects according to the present disclosure are not limited to the contents exemplified above, and more various effects are included in the present specification.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a block diagram of a flexible display device according to an embodiment of the present disclosure.

FIG. 2 is a circuit diagram of a sub-pixel of the flexible display device according to an embodiment of the present disclosure.

FIG. 3 is a plan view of the flexible display device according to an embodiment of the present disclosure.

FIG. 4 is a perspective view of the flexible display device according to an embodiment of the present disclosure.

FIG. 5 is a perspective view illustrating a bent state of the flexible display device according to an embodiment of the present disclosure.

FIG. 6A is a cross-sectional view taken along line I-I′ of FIG. 3.

FIG. 6B is a cross-sectional view taken along line II-II′ of FIG. 3.

FIG. 7 is a view illustrating a portion of a cross-section of the flexible display device according to an embodiment of the present disclosure.

FIG. 8 is a side view of the flexible display device of FIG. 7.

FIG. 9 is a view illustrating a portion of a cross-section of a flexible display device according to another embodiment of the present disclosure as an example.

### DETAILED DESCRIPTION OF THE EMBODIMENTS

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

In construing an element, the element is construed as including an error range although there is no explicit description.

In describing a position relationship, for example, when a position relation between two parts is described as “on,” “over,” “under,” and “next” one or more other parts can be disposed between the two parts unless “just(ly)” or—“direct(ly)” is used.

In describing a time relationship, for example, when the temporal order is described as ‘after^{˜}’, ‘subsequent^{˜}’, ‘next^{˜}’, and ‘before^{˜}’, a case which is not continuous can be included unless “just(ly)” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing the elements of the present disclosure, terms such as first, second, A, B, (a), (b), etc., can be used. Such terms are used for merely discriminating the corresponding elements from other elements and the corresponding elements are not limited in their essence, sequence, precedence, or number by the terms. It will be understood that when an element is referred to as being “coupled” or “connected to” another element, it can be directly coupled or directly connected to the other element, or intervening other elements can be present therebetween.

The term “at least one” should be understood as including any and all combinations of one or more of the associated listed elements. For example, the meaning of “at least one of a first element, a second element, and a third element” denotes the combination of all elements proposed from two or more of the first element, the second element, and the third element as well as the first element, the second element, or the third element.

In the present disclosure, examples of a display device can include a narrow-sense display device such as a quantum dot module, an organic light emitting diode (OLED) module or a liquid crystal module (LCM) having a display panel and a driver for driving the display panel. Also, examples of the display device can include a set device (or a set apparatus) or a set electronic apparatus such as a notebook computer, a TV, a computer monitor, an equipment apparatus including an automotive apparatus or another type of apparatus for vehicles, or a mobile electronic device such as a smartphone or an electronic pad, which is a complete product (or a final product) including an LCM, an OLED module, and a quantum dot (QD) module.

Therefore, in the present disclosure, examples of the display device can include a narrow-sense display device itself, such as an LCM, an OLED module, and a QD module, and a set device, which is a final consumer device or an application product including the LCM, the OLED module, and the QD module.

In some embodiments, an LCM, an OLED module, and a QD module including a display panel and a driver can be referred to as a narrow-sense display device, and an electronic device, which is a final product including an LCM, an OLED module, and a QD module can be referred to as a set device. For example, the narrow-sense display device can include a display panel, such an LCM, an OLED module, or a QD module, and a source printed circuit board (PCB), which is a controller for driving the display panel. The set device can further include a set PCB, which is a set controller electrically connected to the source PCB to overall control the set device.

A display panel applied to embodiments of the present disclosure can use any type of display panel, including a liquid crystal display panel, an organic light emitting diode (OLED) display panel, a quantum dot (QD) display panel, and an electroluminescent display panel. The display panel of the embodiment is not limited to a specific display panel capable of bezel bending with a flexible substrate for an organic light emitting diode (OLED) display panel and a lower back plate support structure. Also, a shape or a size of a display panel applied to a display device according to these embodiments is not limited.

In an example where the display panel is the organic light emitting display panel, the display panel can include a plurality of gate lines, data lines, and pixels respectively provided in intersections of the gate lines and the data lines. Also, the display panel can include an array including a thin film transistor (TFT), which is an element for selectively applying a voltage to each of the pixels, an light emitting element layer on the array, and an encapsulation substrate or an encapsulation layer disposed on the array to cover the light emitting element layer. The encapsulation substrate can protect the TFT and the light emitting element layer from an external impact and can prevent water (or moisture) or oxygen from penetrating into the light emitting element layer. Also, a layer provided on the array can include an inorganic light emitting layer, for example, a nano-sized material layer, a quantum dot, or the like.

Features of various embodiments of the present disclosure can be partially or overall coupled to or combined with each other, and can be variously inter-operated with each other and driven technically. Embodiments of the present disclosure can be carried out independently from each other, or can be carried out together in co-dependent relationship. Hereinafter, embodiments of the present disclosure are considered through the accompanying drawings and Examples as follows. Since scales of components shown in the drawings have different scales from actual ones for convenience of explanation, they are not limited to the scales shown in the drawings. Further, all the components of each flexible display device according to all embodiments of the present disclosure are operatively coupled and configured.

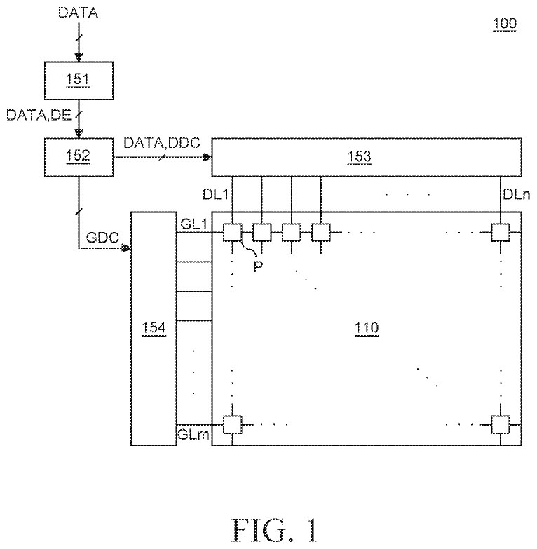

FIG. 1 is a block diagram of a flexible display device according to an embodiment of the present disclosure.

Referring to FIG. 1, a flexible display device 100 according to the embodiment of the present disclosure can include an image processing unit 151, a timing controller 152, a data driver 153, a gate driver 154, and a display panel 110.

In this case, the image processing unit 151 can output a data signal DATA and a data enable signal DE that are supplied from the outside. The image processing unit 151 can output one or more of a vertical synchronization signal, a horizontal synchronization signal, and a clock signal, in addition to the data enable signal DE.

The timing controller 152 is supplied with the data enable signal DE or the data signal DATA, together with driving signals including the vertical synchronization signal, the horizontal synchronization signal, the clock signal and the like, from the image processing unit 151. The timing controller 152 can output a gate timing control signal GDC for controlling an operational timing of the gate driver 154 and a data timing control signal DDC for controlling an operational timing of the data driver 153 based on the driving signals.

In addition, the data driver 153 samples and latches the data signal DATA supplied from the timing controller 152 in response to the data timing control signal DDC supplied from the timing controller 152, and converts the data signal DATA into a gamma reference voltage to output it. The data driver 153 can output the data signal DATA through data lines DL1 to DLn.

In addition, the gate driver 154 can output a gate signal while shifting a level of a gate voltage in response to the gate timing control signal GDC supplied from the timing controller 152. The gate driver 154 can output the gate signal through gate lines GL1 to GLm.

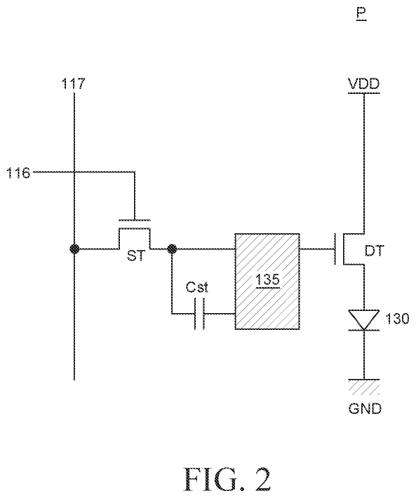

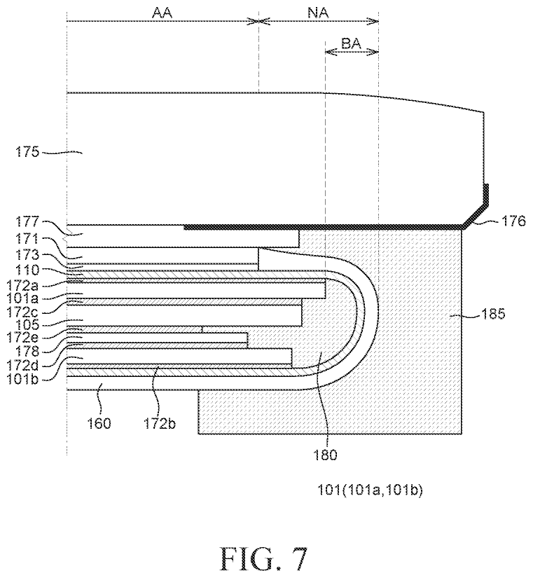

The display panel 110 can display an image while sub-pixels P emit light in response to the data signal DATA and the gate signal supplied from the data driver 153 and the gate driver 154. A detailed structure of the sub-pixel P will be described in detail in FIG. 2 and FIG. 7A. For instance, each sub-pixel P of FIG. 1 can have the configuration of the sub-pixel P in FIG. 2 and FIG. 7A.

FIG. 2 is a circuit diagram of a sub-pixel of the flexible display device according to an embodiment of the present disclosure.

Referring to FIG. 2, the sub-pixel of the flexible display device according to an embodiment of the present disclosure can include a switching transistor ST, a driving transistor DT, a compensation circuit 135, and a light emitting element 130.

The light emitting element 130 can operate to emit light according to a driving current formed by the driving transistor DT.

The switching transistor ST can perform a switching operation such that a data signal supplied through a data line 117 is stored as a data voltage in a capacitor CST, in response to a gate signal supplied through a gate line 116.

The driving transistor DT can operate such that a constant driving current flows between a high potential power line VDD and a low potential power line GND in response to the data voltage stored in the capacitor CST.

The compensation circuit 135 is a circuit for compensating for a threshold voltage or the like of the driving transistor DT, and the compensation circuit 135 can include one or more thin film transistors and a capacitor. A configuration of the compensation circuit 135 can vary according to a compensation method.

The sub-pixel shown in FIG. 2 is configured to have a structure of 2T(Transistor)1C(Capacitor) including the switching transistor ST, the driving transistor DT, the capacitor CST, and the light emitting element 130. However, the sub-pixel can be configured to have a variety of structures, such as 3T1C, 4T2C, 5T2C, 6T1C, 6T2C, 7T1C, 7T2C, and the like when the compensation circuit 135 is added thereto.

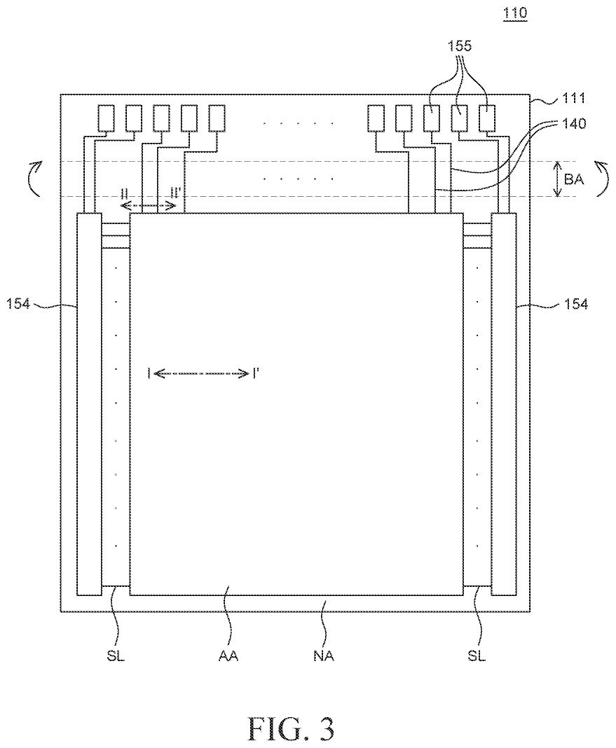

FIG. 3 is a plan view of the flexible display device according to an embodiment of the present disclosure.

In particular, FIG. 3 illustrates, for example, a state in which a flexible substrate 111 of the flexible display device 100 according to an embodiment of the present disclosure is not bent.

Referring to FIG. 3, the display panel 110 in the flexible display device 100 according to an embodiment of the present disclosure can include an active area AA in which pixels actually emitting light through thin film transistors and light emitting elements on the substrate 111 are disposed, and a non-active area NA, which is a bezel area surrounding edges of the active area AA. That is, the non-active area NA can surround all of the edges of the active area AA.

In the non-active area NA of the substrate 111, circuits such as the gate driver 154 and the like for driving the flexible display device 100 and various signal lines, such as scan lines SL (used to scan the display panel from top to bottom), gate lines, vertical sync lines (VSYN), horizontal sync lines (HSYNC), data clock (DCLK), etc. can be disposed.

The circuit for driving the flexible display device 100 can be disposed on the substrate 111 in a gate in panel (GIP) manner, or can be connected to the substrate 111 in a tape carrier package (TCP) or chip on film (COF) manner.

A plurality of pads 155 are disposed on one side of the substrate 111 in the non-active area NA, so that external modules can be bonded thereto.

Meanwhile, a bending area BA can be formed by bending a portion of the non-active area NA of the substrate 111 in a bending direction as indicated by the two arrows of FIG. 3.

The non-active area NA of the substrate 111 is an area in which lines and driving circuits for driving a screen are disposed. Since the non-active area NA is not an area in which an image is displayed, it is unnecessary to be viewed from an upper surface of the substrate 111. That is, the non-active area NA does not include pixels for emitting light, and such, can be disposed in a bent shape, which is not to be viewed by a user. Accordingly, while securing an area for the lines and driving circuits by bending a portion of the non-active area NA of the substrate 111, a bezel area can be reduced.

For example, various lines can be formed on the substrate 111. The lines can be formed in the active area AA of the substrate 111, or lines 140 formed in the non-active area NA can connect the driving circuits, the gate driver, the data driver, and the like to each other to transfer signals.

For example, the lines 140 are formed of a conductive material, and can be formed of a conductive material having excellent ductility in order to reduce the occurrence of cracks when the substrate 111 (including the non-active area) is bent. For example, the lines 140 can be formed of a conductive material having excellent ductility such as gold (Au), silver (Ag), or aluminum (Al) or a combination thereof, and can be formed of one of various conductive materials used in the active area AA. The lines 140 can also be formed of at least one of molybdenum (Mo), chromium (Cr), titanium (Ti), nickel (Ni), neodymium (Nd), copper (Cu), and alloys of silver (Ag) and magnesium (Mg) or a combination thereof.

The lines 140 can be formed of a multilayer structure including various conductive materials, and can be formed of a three-layer structure of titanium (Ti)/aluminum (Al)/titanium (Ti), for example, but the present disclosure is not limited thereto.

The lines 140 formed in the bending area BA are subjected to tensile force(s) when bent. For example, the lines 140 extending in the same direction as a bending direction are subjected to greatest tensile force, so cracks or disconnection (e.g., dislocations) can occur therein. Therefore, rather than disposing the lines 140 to extend in the bending direction, at least a portion of the lines 140 disposed in an area including the bending area BA are disposed to extend in a diagonal direction (e.g., different than, such as transverse to, the bending direction), which is a direction different from the bending direction, so that the tensile force can be minimized.

The lines 140 disposed in an area including the bending area BA can be variously shaped, and can be formed in a shape such as a trapezoidal wave shape, a triangular wave shape, a sawtooth wave shape, a sinusoidal wave shape, an omega (Ω) shape, a rhombus shape, or the like.

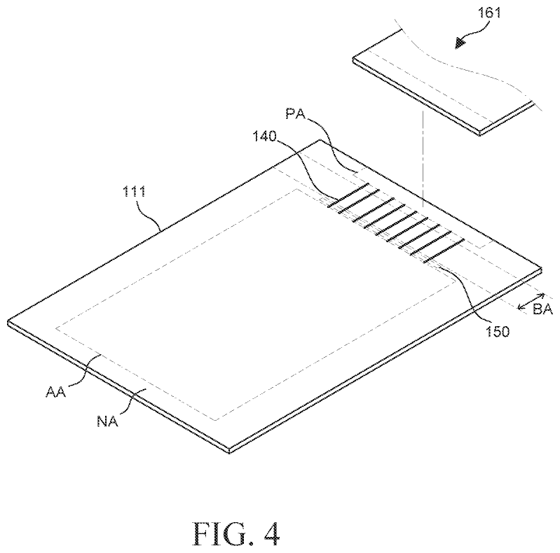

FIG. 4 is a perspective view of the flexible display device according to an embodiment of the present disclosure.

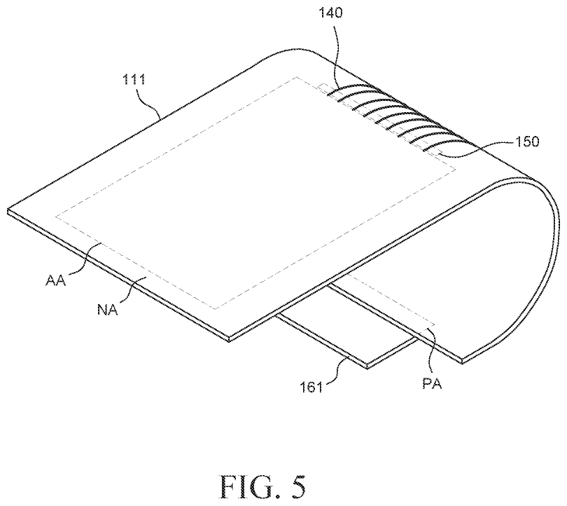

FIG. 5 is a perspective view illustrating a bent state of the flexible display device according to an embodiment of the present disclosure.

FIGS. 4 and 5 illustrate a case where one side of the flexible display device, for example, a lower side of the flexible display device is bent.

Referring to FIG. 4, the flexible display device according to an embodiment of the present disclosure can include the substrate 111 and a circuit element 161.

The substrate 111 can be divided into an active area AA and a non-active area NA which is a bezel area surrounding edges of the active area AA.

The non-active area NA can further include a pad area PA positioned outside the bending area BA.

A plurality of sub-pixels can be disposed in the active area AA. The sub-pixels can be arranged in a manner of R (red), G (green) and B (blue), or in a manner of R, G, B, and W (white) in the active area AA to thereby realize a full color. The sub-pixels can be divided by gate lines and data lines that intersect each other.

The circuit element 161 can include bumps (or terminals). The bumps of the circuit element 161 can be respectively bonded to pads of the pad area PA through anisotropic conductive films (ACF), which is a type of adhesive that can allow for electrical conduction only in the thickness direction and has good mechanical strength and high electrical conductivity.

The circuit element 161 can be a chip on film (COF) in which a driver integrated circuit (IC) is mounted on a flexible film. In addition, the circuit element 161 can be implemented as a chip on glass (COG) type, in which it is directly bonded to the pads on the substrate 111 by a COG process. The COG process is a manufacturing process for displays that integrates the display driver electronics onto the glass substrate of the display. This eliminates the need for a separate printed circuit board (PCB). Further, the circuit element 161 can be a flexible circuit such a flexible printed circuit (FPC) or a flexible flat cable (FFC). However, in the following embodiments, the COF is mainly described as an example of the circuit element 161, but the present disclosure is not limited thereto.

Driving signals supplied through the circuit element 161, for example, a gate signal and a data signal can be supplied to the gate line and the data line of the active area AA through the lines 140, such as routing lines.

In the flexible display device, a sufficient space in which the pad area PA, the circuit element 161, and the like can be positioned should be secured, in addition to the active area AA in which an input image is implemented. Such a space for securing the pad area PA, the circuit element 161 can correspond to a bezel area, and the bezel area can be recognized by a user positioned in front of the flexible display device and can be a factor in lowering aesthetics. That is, the bezel area can form a front surface of the flexible display device that is potentially undesired by a user.

Referring to FIG. 5, in the flexible display device according to an embodiment of the present disclosure, a lower edge of the substrate 111 can be bent in a rear direction to have a predetermined curvature.

The lower edge of the substrate 111 can correspond to an outside portion of the active area AA, and can correspond to an area in which the pad area PA is positioned. As the substrate 111 is bent, the pad area PA can be positioned to overlap the active area AA in the rear of the active area AA. Accordingly, the bezel area recognized from the front of the flexible display device 100 can be minimized (e.g., the bezel area can be reduced). Accordingly, a bezel width can be reduced to thereby provide an effect of improving an aesthetic sense.

To this end, the substrate 111 can be formed of a flexible, bendable material. For example, the substrate 111 can be formed of a plastic material such as polyimide (PI), polyester, polycarbonate, etc. In addition, the lines 140 can be formed of a material having flexibility (e.g., can be elastically deformed). For example, the lines 140 can be formed of a material such as a metal nano wire, metal mesh, or carbon nanotube (CNT). However, the present disclosure is not limited thereto.

In addition, the lines 140 according to an embodiment of the present disclosure can be disposed in a multilayer structure (e.g., a double wiring structure) in the non-active area NA including the bending area BA. As a result, a margin is created in line arrangement, and designing line/electrode arrangement can be facilitated.

Meanwhile, in order to reduce the bezel area, an outer frame of the flexible display device can be formed using ultraviolet (UV) resin or heat curing resin instead of a metal frame according to the related art. However, when the resin is cured using UV, the resin can permeate into the flexible display device that is bent and thus, may not be cured (or may not be fully cured). Also, the lines 140 pass through the bezel area, and curing of the resin permeated into the flexible display device can be hindered by the lines 140.

Accordingly, according to an embodiment of the present disclosure, by uniformly and completely curing resin for inner side sealing and outer side sealing in the bending area BA through addition of a reflective layer 150 under the lines 140 in the bezel area to reflect UV light, it is possible to prevent assembly defects due to leakage of uncured resin, which will be described in detail with reference to the drawings.

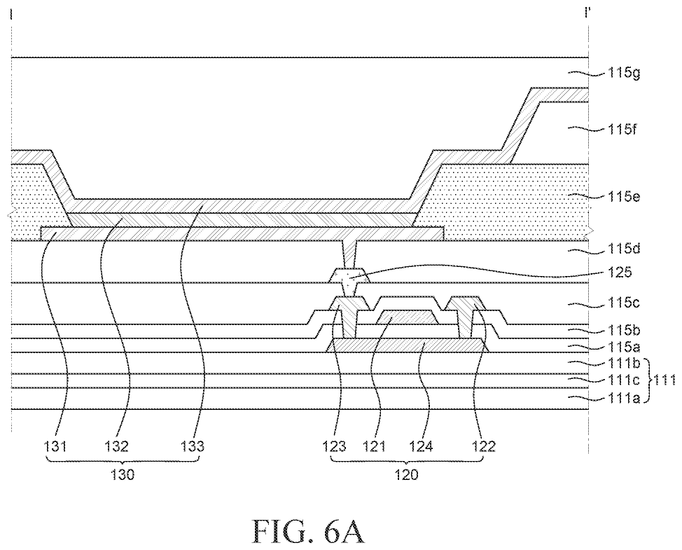

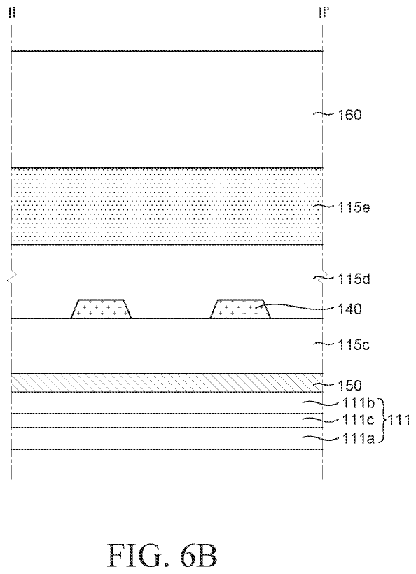

FIG. 6A is a cross-sectional view taken along line I-I′ of FIG. 3.

FIG. 6B is a cross-sectional view taken along line II-II′ of FIG. 3.

FIG. 7 is a view illustrating a portion of a cross-section of the flexible display device according to an embodiment of the present disclosure.

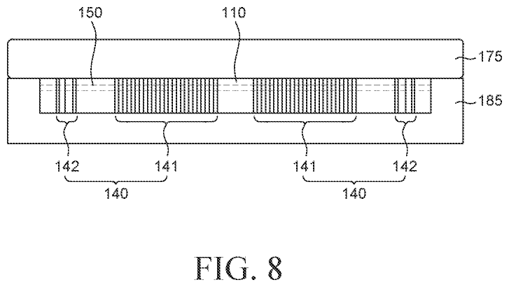

FIG. 8 is a side view of the flexible display device of FIG. 7.

FIG. 8 illustrates the display panel 110, the lines 140, and the reflective layer 150 exposed for convenience of description, but the display panel 110, the lines 140, and the reflective layer 150 can be covered and not exposed by providing a micro-coating layer (MLC) 160 and an outer sealing part 185.

FIG. 6A illustrates a cross-sectional structure of the active area AA described in FIG. 3 in detail, and FIG. 6B illustrates a cross-sectional structure of the non-active area NA between the active area AA and the bending area BA in detail.

FIG. 7 illustrates a cross-section of a lower side of the flexible display device according to an embodiment of the present disclosure, which is bent.

FIG. 8 is a view of the flexible display device of FIG. 7 viewed from a right side.

Referring to FIG. 6A, the substrate 111 serves to support and protect components of the flexible display device disposed thereon.

Recently, the substrate 111 can be formed of a ductile (e.g., elastic) material having flexible characteristics, such as plastic. That is, the substrate 111 can have a predetermined elastic deformation to permit a predetermined degree of bending.

The substrate 111 can be in a form of film including one of a polyester-based polymer, a silicone-based polymer, an acrylic-based polymer, a polyolefin-based polymer, and a copolymer thereof.

The substrate 111 can include a first substrate 111a, a second substrate 111b, and an insulating layer 111c. The insulating layer 111c can be disposed between the first substrate 111a and the second substrate 111b. In this way, by configuring the substrate 111 with the first substrate 111a, the second substrate 111b, and the insulating layer 111c, penetration of moisture can be prevented. For example, the first substrate 111a and the second substrate 111b can be polyimide (PI) substrates. The insulating layer 111c can be in the form of a film, and can provide sound insulation, vibration insulation, and can insulate the flexible display device (e.g., the substrate 111) from outside elements, such as water, particulate matter, and the like.

A buffer layer can be further disposed on the substrate 111 (e.g., disposed on a top surface of the substrate 111). The buffer layer prevents penetration of moisture or other impurities from the outside through the substrate 111 and can planarize a surface of the substrate 111. The buffer layer is not necessarily a necessary component, and can be deleted depending on a type of a thin film transistor 120 disposed on the substrate 111.

The thin film transistor 120 is disposed on the substrate 111.

For example, the thin film transistor 120 can include a gate electrode 121, a semiconductor layer 124, a source electrode 122, a drain electrode 123.

For example, the semiconductor layer 124 can be formed of amorphous silicon or polycrystalline silicon, but is not limited thereto. Polycrystalline silicon has superior mobility as compared to amorphous silicon and low energy power consumption and excellent reliability, and thus, can be applied to a driving thin film transistor within the pixel.

In addition, for example, the semiconductor layer 124 can be formed of an oxide semiconductor. The oxide semiconductor has excellent mobility and uniformity properties.

The oxide thin film transistor 120, in which the semiconductor layer 124 is formed of an oxide semiconductor, is capable of gate in panel (GIP) driving at 1-10 Hz based on excellent off-current characteristics compared to Low Temperature Polycrystalline Silicon (LTPS) thin film transistors according to the related art, and thus, can realize low power driving (e.g., lower power driving as compared to the related art).

The semiconductor layer 124 can include a source region and a drain region including a p-type or n-type impurity, and a channel region between the source region and the drain region. The semiconductor layer 124 can further include a low concentration-doped region between the source region and the drain region adjacent to the channel region.

The source region and the drain region are doped with a high concentration of impurity, and can be connected to the source electrode 122 and the drain electrode 123 of the thin film transistor 120, respectively.

As an impurity ion, the p-type impurity or n-type impurity can be used. The p-type impurity can be one of boron (B), aluminum (Al), gallium (Ga), and indium (In) or a combination thereof, and the n-type impurity can be one of phosphorus (P), arsenic (As), and antimony (Sb) or a combination thereof.

In addition, the channel region of the semiconductor layer 124 can be doped with the n-type impurity or p-type impurity according to an n-channel metal-oxide-semiconductor (NMOS) or p-channel metal-oxide-semiconductor (PMOS) thin film transistor structure, and the thin film transistor included in the flexible display device according to an embodiment of the present disclosure can be an NMOS or PMOS thin film transistor.

A first insulating layer 115a can be disposed on the semiconductor layer 124.

The first insulating layer 115a is an insulating layer configured as a single layer of silicon oxide (SiOx) or silicon nitride (SiNx) or multiple layers thereof, and can be disposed such that a current flowing through the semiconductor layer 124 does not flow to the gate electrode 121. In addition, silicon oxide is less ductile than metal, but is superior in ductility to silicon nitride, and can be formed as a single layer or multiple layers depending on characteristics thereof.

The gate electrode 121 can be disposed on the first insulating layer 115a.

The gate electrode 121 serves as a switch for turning on or turning off the thin film transistor 120 based on an electric signal transmitted from the outside through the gate line, and can be configured as a single layer or multiple layers of a conductive metal such as copper (Cu), aluminum (Al), molybdenum (Mo), chromium (Cr), gold (Au), titanium (Ti), nickel (Ni), and neodymium (Nd), or alloys thereof. However, the present disclosure is not limited thereto. The electrical signal can be transmitted from an input source, such as an internet source, and can be used to control the flow of electrons in the thin film transistor 1020.

A second insulating layer 115b can be disposed on the gate electrode 121.

For example, the second insulating layer 115b serves to insulate the gate electrode 121, and the source electrode 122 and the drain electrode 123 from each other, and can be configured as a single layer or multiple layers of silicon oxide (SiOx) or silicon nitride (SiNx), but is not limited thereto and alternative material can be used.

The source electrode 122 and the drain electrode 123 can be disposed on the second insulating layer 115b.

The source electrode 122 and the drain electrode 123 are connected to the data line, and can enable an electric signal transmitted from the outside to be transmitted from the thin film transistor 120 to the light emitting element 130. The source electrode 122 and the drain electrode 123 can be configured as a single layer or multiple layers of a conductive metal such as copper (Cu), aluminum (Al), molybdenum (Mo), chromium (Cr), gold (Au), titanium (Ti), nickel (Ni), and neodymium (Nd), or alloys thereof. However, the present disclosure is not limited thereto.

A passivation layer formed of an inorganic insulating layer, such as silicon oxide (SiOx) or silicon nitride (SiNx) can be further disposed on the thin film transistor 120 configured as described above.

The passivation layer can prevent unnecessary electrical connections between components disposed over and under the passivation layer and prevent contamination or damage from the outside. The passivation layer can be omitted depending on configurations and characteristics of the thin film transistor 120 and the light emitting element 130.

Structures of the thin film transistor 120 can be divided into an inverted-staggered structure and a coplanar structure according to positions of elements constituting the thin film transistor 120. For example, the thin film transistor having an inverted-staggered structure refers to a thin film transistor having a structure in which a gate electrode is positioned opposite to a source electrode and a drain electrode based on a semiconductor layer. For instance, an inverted-staggered thin film transistor (TFT) is a type of TFT in which the gate electrode is located on the bottom of the device (e.g., flexible display device), and the source and drain electrodes are located on the top of the device. On the other hand, as in FIG. 6A, the thin film transistor 120 having a coplanar structure refers to a thin film transistor having a structure in which the gate electrode 121 is positioned on the same side as the source electrode 122 and the drain electrode 123 based on the semiconductor layer 124.

In FIG. 6A, the thin film transistor 120 having a coplanar structure is illustrated, but the flexible display device according to an embodiment of the present disclosure can also include a thin film transistor having an inverted-staggered structure.

For convenience of description, only a driving thin film transistor 120 is illustrated from among various thin film transistors that can be included in the flexible display device, but a switching thin film transistor, a capacitor, or the like can also be included in the flexible display device. When a signal is applied from the gate line to the switching thin film transistor, the switching thin film transistor can transmit a signal from the data line to the gate electrode 121 of the driving thin film transistor 120. In addition, the driving thin film transistor 120 can transmit a current transferred through power lines to an anode 131 by the signal transmitted from the switching thin film transistor, and control light emission by the current transmitted to the anode 131.

Planarization layers 115c and 115d can be disposed on the thin film transistor 120. The planarization layers 115c and 115d can be disposed to protect the thin film transistor 120, to alleviate a step caused by the thin film transistor 120, and to reduce parasitic capacitance generated between the thin film transistor 120 and the gate line and the data line, and the light emitting elements 130.

For example, the planarization layers 115c and 115d can be formed of one or more of acrylic resin, epoxy resin, phenolic resin, polyamides resin, polyimides resin, unsaturated polyesters resin, polyphenylene resin, polyphenylene sulfides resin and benzocyclobutene, but are not limited thereto.

As shown in FIG. 6A, the planarization layers 115c and 115d can have a multilayer structure formed of at least two layers, and can include a first planarization layer 115c and a second planarization layer 115d, but are not limited thereto. The first planarization layer 115c is disposed to cover the thin film transistor 120 and can expose portions of the source electrode 122 and the drain electrode 123 of the thin film transistor 120.

The planarization layers 115c and 115d can be overcoat layers, but are not limited thereto.

In addition, an intermediate electrode 125 for electrically connecting the thin film transistor 120 and the light emitting element 130 can be disposed on the first planarization layer 115c. In addition, in FIG. 6A, various metal layers serving as lines/electrodes such as data lines or signal lines can be disposed on the first planarization layer 115c.

In addition, the second planarization layer 115d can be disposed on the first planarization layer 115c and the intermediate electrode 125.

For example, in a first embodiment of the present disclosure, the planarization layers 115c and 115d are formed of two layers due to an increase in various signal lines as the display panel has a higher resolution. Therefore, an additional layer is created since it is difficult to place all of lines on one layer while securing a minimum distance therebetween. Due to the addition of such an additional layer, for example, the second planarization layer 115d, a margin is created in line arrangement, so that designing the arrangement of lines and electrodes can be facilitated. In addition, when a dielectric material is used as the planarization layers 115c and 115d, to form multilayered arrangement, the planarization layers 115c and 115d can also be utilized for the use of forming capacitance between metal layers.

The second planarization layer 115d can be formed such that a portion of the intermediate electrode 125 is exposed, and the drain electrode 123 of the thin film transistor 120 and the anode 131 of the light emitting element 130 can be electrically connected by the intermediate electrode 125.

The light emitting element 130 can be disposed on the second planarization layer 115d.

The light emitting element 130 can include the anode 131, a light emitting unit 132 (e.g., light emitting assembly), and a cathode 133.

The anode 131 can be disposed on the second planarization layer 115d.

The anode 131 serves to supply holes to the light emitting unit 132 and can be connected to the intermediate electrode 125 through a contact hole in the second planarization layer 115d to thereby be electrically connected to the thin film transistor 120.

The anode 131 can be formed of a transparent conductive material, such as indium tin oxide (ITO), indium zinc oxide (IZO), or the like, but is not limited thereto.

When the flexible display device is a top emission type display device that emits light to an upper portion thereof where the cathode 133 is disposed, it can further include a reflective layer such that the emitted light is reflected from the anode 131 to be smoothly emitted in a direction toward the upper portion, and the cathode 133 is disposed at the upper portion. For example, the anode 131 can be a two-layer structure in which a transparent conductive layer formed of a transparent conductive material and a reflective layer are sequentially stacked, or a three-layer structure in which a transparent conductive layer, a reflective layer and a transparent conductive layer are sequentially stacked. The reflective layer can be formed of silver (Ag) or an alloy including silver. However, the present disclosure is not limited thereto, and the flexible display device can be applied to a bottom emission type display device.

A bank 115e can be disposed on the anode 131 and the second planarization layer 115d

The bank 115e can define the sub-pixels by dividing areas that actually emits light. For example, after forming a photoresist on the anode 131, the bank 115e can be formed by photolithography.

Photoresist refers to a photosensitive resin in which solubility in a developer is changed by the action of light, and a specific pattern can be obtained by exposing and developing the photoresist. Types of photoresist can be classified into a positive photoresist and a negative photoresist. The positive photoresist is a photoresist where solubility of an exposed portion in a developer is increased by exposure. When the positive photoresist is developed, a pattern from which the exposed portion is removed can be obtained. The negative photoresist is a photoresist where solubility of the exposed portion in the developer is significantly lowered by the exposure. When the negative photoresist is developed, a pattern from which non-exposed portions are removed can be obtained.

A fine metal mask (FMM) which is a deposition mask, can be used to form the light emitting unit 132 of the light emitting element 130.

For example, to prevent damage that can occur due to contact with the deposition mask disposed on the bank 115e and to maintain a constant distance between the bank 115e and the deposition mask, a spacer 115f formed of one of polyimide, photo acryl, and benzocyclobutene (BCB) can be disposed on the bank 115e.

The light emitting unit 132 (e.g., light emitting assembly) can be disposed between the anode 131 and the cathode 133.

The light emitting unit 132 serves to emit light and can include at least one of a hole injection layer (HIL), a hole transport layer (HTL), a light emitting layer, an electron transport layer (ETL), and an electron injection layer (EIL), and some components thereof can be omitted depending on a structure or characteristics of the flexible display device. Here, an electroluminescent layer and an inorganic emitting layer can be used as the light emitting layer.

The hole injection layer can be disposed on the anode 131 to facilitate an injection of holes.

The hole transport layer can be disposed on the hole injection layer to smoothly transport holes to the light emitting layer.

The light emitting layer can be disposed on the hole transport layer and can include a material capable of emitting light of a specific color to thereby emit light of a specific color. In addition, a luminescent material can be formed using a phosphorescent material or a fluorescent material.

The electron injection layer can be further disposed on the electron transport layer. The electron injection layer is an organic layer that facilitates an injection of electrons from the cathode 133 and can be omitted depending on the structure and characteristics of the flexible display device 100.

Meanwhile, at a position adjacent to the light emitting layer, an electron blocking layer or a hole blocking layer that blocks a flow of holes or electrons is further disposed to thereby prevent a phenomenon in which when electrons are injected into the light emitting layer, the electrons move from the light emitting layer and pass to the adjacent hole transport layer or a phenomenon in which when holes are injected into the light emitting layer, the holes move from the light emitting layer and pass to the adjacent electron transport layer, so that luminous efficiency can be improved. An electron blocking layer (EBL) is a layer of semiconductor material that is used to prevent electrons from flowing from one region of a device to another. EBLs can prevent electrons from flowing from the active region to the p-type layer, which would reduce the efficiency of the LED. A hole blocking layer (HBL) is a layer of semiconductor material that is used to prevent holes from flowing from one region of a device to another.

The cathode 133 is disposed on the light emitting unit 132 and serves to supply electrons to the light emitting unit 132. Since the cathode 133 needs to supply electrons, it can be formed of a metal material, such as magnesium (Mg), silver-magnesium, which is a conductive material having a low work function, but is not limited thereto.

When the flexible display device is a top emission type display device, the cathode 133 can be a transparent conductive oxide, such as indium tin oxide (ITO), indium zinc oxide (IZO), indium tin zinc oxide (ITZO), zinc oxide (ZnO), and tin oxide (TO).

For example, an encapsulation part 115g can be disposed on the light emitting element 130 to prevent the thin film transistor 120 and the light emitting element 130, which are components of the flexible display device 100, from being oxidized or damaged due to moisture, oxygen, or impurities introduced from the outside. The encapsulation part 115g can be formed by stacking a plurality of encapsulation layers, a foreign material compensation layer, and a plurality of barrier films.

The encapsulation layer can be disposed on an entire surface of upper portions of the thin film transistor 120 and the light emitting element 130, and can be formed of one of silicon nitride (SiNx) or aluminum oxide (AlyOz), where “y” and “z” are non-zero integer numbers, which is an inorganic material. However, the present disclosure is not limited thereto.

The foreign material compensation layer is disposed on the encapsulation layer, and an organic material, such as silicon oxycarbon (SiOCz), acrylic (acryl), or epoxy-based resin can be used for the foreign material compensation layer. However, the present disclosure is not limited thereto. When a defect occurs due to a crack generated by a foreign material or particles that can be generated during a process, it can be compensated for by covering the foreign material or particles by the foreign material compensation layer.

A barrier film can be disposed on the encapsulation layer and the foreign material compensation layer, whereby the flexible display device can delay the penetration of oxygen and moisture from the outside. The barrier film is configured (e.g., is constructed) in the form of a light-transmissive component and double-sided adhesive film, and can be formed of any one of olefin-based, acrylic-based, and silicon-based insulating materials. Alternatively, a barrier film formed of any one of cycloolefin polymer (COP), cycloolefin copolymer (COC) and Polycarbonate (PC) can be further stacked (e.g., sequentially stacked in any order), but is not limited thereto.

For example, a polarizing film can be disposed on the encapsulation part 115g.

Also, a touch panel can be disposed on a top of the polarizing film. However, the present disclosure is not limited thereto, and the polarizing film can be disposed on the touch panel.

The touch panel is an input method in which a user can directly input information on a screen by pressing a display screen with a hand (e.g., of the user) or a pen. For example, the touch panel is evaluated as the most ideal input method in a graphical user interface (GUI) environment because a user can directly perform a desired operation while looking at the screen, and anyone can easily operate it. The touch panel is widely used in various fields of application, such as mobile terminals, banks government offices, various types of medical equipment, and guidance of tourism and major institutions.

Next, the cross-sectional structure of the non-active area will be described with reference to FIG. 6B.

As described above, FIG. 6B illustrates the cross-sectional structure of the non-active area between the active area and the bending area in detail.

Some components of FIG. 6B are substantially the same as or similar to the components described in FIG. 6A, and description thereof will be omitted.

The gate signal and data signal described in FIGS. 1 to 3 can be transferred from the outside to pixels disposed in the active area through the lines 140 disposed in the non-active area of the flexible display device, so that light can be emitted.

For example, the lines 140 are formed of a conductive material, and can be formed of a conductive material having excellent ductility in order to reduce the occurrence of cracks when the substrate 111 is bent.

For example, the lines 140 can be formed of a conductive material having excellent ductility such as gold (Au), silver (Ag), or aluminum (Al). For example, the lines 140 can be formed of one of various conductive materials used in the active area. The lines 140 can also be formed of molybdenum (Mo), chromium (Cr), titanium (Ti), nickel (Ni), neodymium (Nd), copper (Cu), silver (Ag) or magnesium (Mg) or alloys thereof. For example, the lines 140 can be formed of a multilayer structure including various conductive materials, and can be formed of a three-layer structure of titanium (Ti)/aluminum (Al)/titanium (Ti), but the present disclosure is not limited thereto.

In addition, a buffer layer formed of an inorganic insulating layer can be disposed below the lines 140 to protect the lines 140, and a protective layer formed of an inorganic insulating layer is formed to surround upper and side portions of the lines 140. Thus, a phenomenon such as corrosion of the lines 140 by reaction thereof with moisture or the like can be prevented.

The lines 140 formed in the bending area are subjected to tensile force(s) when bent. As described with reference to FIG. 3, the lines 140 extending in the same direction as the bending direction on the substrate 111 receive greatest tensile force, and cracks can occur within the lines 140. If the cracks are severe, disconnection of the lines can occur. Therefore, rather than disposing the lines 140 to extend in the bending direction, at least a portion of the lines 140 disposed in an area including the bending area are disposed to extend in a diagonal direction (e.g., diagonal from the bending direction), which is a direction different from the bending direction, so that the tensile force can be minimized and the occurrence of cracks can be reduced. That is, by disposing the lines 140 in a diagonal direction, the lines 140 are exposed to less tensile stress when bent, thereby reducing crack generation. In addition, a shape of the lines 140 can be configured in a shape such as a rhombus shape, a triangular wave shape, a sinusoidal wave shape, a trapezoidal wave shape or the like, but is not limited thereto.

The first planarization layer 115c can be disposed on the substrate 111.

In addition, the lines 140 can be disposed on the first planarization layer 115c.

In addition, the second planarization layer 115d can be disposed on the lines 140. For example, the first planarization layer 115c and the second planarization layer 115d can be formed of one or more of acrylic resin, epoxy resin, phenolic resin, polyamides resin, polyimides resin, unsaturated polyesters resin, polyphenylene resin, polyphenylene sulfides resin, and benzocyclobutene, but are not limited thereto.

The bank 115e and/or the micro-coating layer (MLC) 160 can be disposed on the second planarization layer 115d.

Since tensile force is applied to the lines 140 disposed on the substrate 111 when the substrate is bent to thereby occur cracks in the lines 140, the micro-coating layer 160 can serve to protect the lines 140 by coating resin with a small thickness at a bending position. Meanwhile, as display devices are miniaturized, efforts are being made to reduce a bezel area, which is an outer portion of an active area, in order to increase an effective display screen size in the same area of the display device.

In addition, in order to reduce the bezel area, an outer frame of a flexible display device is formed using UV or heat curing resin instead of a metal frame according to the related art. However, when the resin is cured using UV, the resin can permeate into the flexible display device that is bent and thus may not be cured. For example, during UV curing, the resin that permeates into the bent flexible display device leaks out of a bending area without being cured, or a difference in bending stress occurs due to a difference in curing of the resin inside and outside the bending area. That is, the resin can have a different curing time at the inside of the bending area as compared to a curing time at the outside of the bending area, for instance, due to air flow, a temperature difference, and the like. In addition, a delamination phenomenon of components, such as adhesive layers, can occur. Also, lines pass through the bezel area, and curing of the resin permeated into the flexible display device can be hindered by these lines. In order to prevent these defects, an additional process of blocking gaps in both sides of the bending area can be performed before UV curing, but due to the additional process, an entire process can be complicated, and uncured resin and delamination of the adhesive layer can still occur.

Accordingly, in an embodiment of the present disclosure, for example, the reflective layer 150 can be disposed under the lines 140 in the non-active area between the active area and the bending area.

For example, the reflective layer 150 can be disposed in a whole electrode shape (or an integral shape of electrode) in an entirety of the non-active area adjacent to the bending area (see FIGS. 4-5), but is not limited thereto. For example, in a plan view of the flexible display device, the reflective layer 150 can be formed in a shape of islands (e.g., or a single “island” or strip of material) and disposed along the lines 140 between the lines 140.

For example, the reflective layer 150 reflects light (e.g., UV light) incident from a side surface of the flexible display device and/or a lower portion of the flexible display device, that is, a lower portion of the flexible display device in which the bent substrate 111 is located, so that an inner sealing part 180 and the outer sealing part 185 in the bending area can be uniformly and completely cured. The reflective layer 150 can be formed as a single layer or multilayer structure formed of any one of opaque metals, such as aluminum (Al), nickel (Ni), chromium (Cr), tungsten (W), titanium (Ti), neodymium (Nd), molybdenum (Mo), and copper (Cu), or alloys thereof. However, embodiments of the present disclosure are not limited thereto.

For example, the reflective layer 150 reflects UV light passing through the micro-coating layer 160, the bank 115e, the first planarization layer 115c, and the second planarization layer 115d in the bending area and the non-active area around the bending area, so that the inner sealing part 180 inside the bending area can be additionally cured. Accordingly, it is possible to prevent assembly defects due to leakage of uncured resin (e.g., by the formation of the inner sealing part 180 or the outer sealing part 185). In addition, an effect of preventing assembly defects caused by a difference in curing between the inner sealing part 180 and the outer sealing part 185 without an additional process is provided.

For example, the reflective layer 150 can be disposed on a flat portion of the non-active area between the active area and the bending area to prevent UV light incident from a side surface of the bending area from being incident into the bending area.

When UV light is incident from the lower portion of the flexible display device, that is, for example, from the lower portion of the bent substrate 111 in which the pad area is located, the reflective layer 150 can be disposed in a direction opposite to a direction in which the UV light is incident. For example, the reflective layer 150 can be disposed on an upper portion of the substrate 111 in the non-active area between the active area and the bending area, which is opposite to the bent substrate 111 so as not to interfere with the incident UV light.

In this case, for example, the reflective layer 150 can be disposed under the lines 140 on the substrate 111 in the non-active area between the active area and the bending area so that incident UV light is not hindered by the lines 140. For example, the reflective layer 150 can be disposed between the substrate 111 and the first planarization layer 115c, but is not limited thereto.

Next, referring to FIGS. 7 and 8, a barrier film 173 can be disposed on the display panel 110.

The barrier film 173 is a component for protecting various components of the flexible display device, and can be disposed to correspond to at least the active area AA of the flexible display device.

For example, the barrier film 173 can include an adhesive material. The adhesive material can be formed of a material, such as pressure sensitive adhesive (PSA), so that it can serve to fix a polarizing plate 171 on the barrier film 173.

The barrier film 173 can be disposed to protect an area larger than the active area AA.

The polarizing plate 171 can be disposed on the barrier film 173 and can suppress reflection of external light on the active area AA. When the flexible display device is externally used, external natural light can be introduced and can be reflected by a reflective layer included in the anode of the light emitting element, or reflected by an electrode formed of opaque metal disposed under the light emitting element. An image of the flexible display device may not be recognized well by the reflected light. The polarizing plate 171 polarizes light introduced from the outside in a specific direction, and can prevent the reflected light from being re-emitted to the outside of the flexible display device.

The polarizing plate 171 can be disposed on the active area AA, but is not limited thereto.

The polarizing plate 171 can be a polarizing plate formed of a polarizer and a protective film protecting the polarizer, or can be formed by coating a polarizing material for flexibility.

An adhesive layer 177 can be disposed on the polarizing plate 171, whereby a cover glass 175 for protecting an exterior of the flexible display device can disposed thereon.

A light blocking layer 176 can be disposed on a lower edge of the cover glass 175.

A back plate 101 can be disposed on a rear surface of the display panel 110.

When a substrate of the display panel 110 is formed of a plastic material, such as polyimide, a manufacturing process of the flexible display device is conducted in a situation in which a support substrate formed of glass is disposed under the display panel 110. After the manufacturing process is completed, the support substrate can be separated and released.

Since a component for supporting the display panel 110 is required even after the support substrate is released, the back plate 101 for supporting the display panel 110 can be disposed under the display panel 110.

For example, the back plate 101 can be disposed adjacent to the bending area BA in other areas of the display panel 110 other than the bending area BA.

For example, the back plate 101 can be formed of a plastic thin film formed of polyimide (PI), polyethylene naphthalate (PEN), polyethylene terephthalate (PET), polymers, or combinations of these polymers.

For example, the display panel 110 can include a first flat portion and a second flat portion, and a curved portion positioned between the first flat portion and the second flat portion.

The first flat portion corresponds to the active area AA having the plurality of sub-pixels and a part of the non-active area NA, and is an area that maintains a flat state. In addition, the second flat portion is an area opposite to the first flat portion, corresponds to a pad portion having pads bonded to circuit elements, and is an area that maintains a flat state (e.g., has planar surface).

Also, the curved portion can correspond to the bending area BA maintaining a bent state with a predetermined curvature.

In this case, for example, the bending area BA can have a “>” shape (e.g., “U” shape). For example, the curved portion extends from the first flat portion and can be bent at an angle of 180 degrees in a rear direction. However, the curved portion can be bent at any angle other than 0 degrees and 360 degrees. Accordingly, the second flat portion extending from the curved portion can be positioned to overlap the first flat portion in the rear of the first flat portion. Accordingly, the circuit element bonded to the second flat portion of the display panel 110 can be positioned in the rear direction of the first flat portion of the display panel 110. However, the present disclosure is not limited thereto.

For example, the back plate 101 can include a first back plate 101a and a second back plate 101b positioned on a rear surface of the first flat portion and a rear surface of the second flat portion, respectively. The first back plate 101a reinforces rigidity of the first flat portion, so that the first flat portion can be maintained in a flat state. The second back plate 101b reinforces rigidity of the second flat portion, so that the second flat portion can be maintained in a flat state. Meanwhile, to secure flexibility of the curved portion and facilitate a control of the neutral plane using the micro-coating layer 160, it is preferable not to position the back plate 101 on a portion of a rear surface of the curved portion.

The first back plate 101a can be bonded to the first flat portion of the display panel 110 by a first adhesive layer 172a, and the second back plate 101b can be bonded to the second flat portion of the display panel 110 by a second adhesive layer 172b. However, the present disclosure is not limited thereto.

For example, a support member 105 is disposed between the first back plate 101a and the second back plate 101b, and the support member 105 can be bonded to the first back plate 101a and the second back plate 101b by a third adhesive layer 172c and a fourth adhesive layer 172d, respectively. For example, the support member 105 can be formed of a plastic material such as polycarbonate (PC), polyimide (PI), polyethylene naphthalate (PEN), polyethylene terephthalate (PET), polymers, combinations of these polymers, or the like. A strength of the support member 105 formed of these plastic materials can be controlled by adding additives to increase a thickness and strength of the support member 105. In addition, the support member 105 can be formed of glass, ceramic, metal or other rigid materials or combinations of the foregoing materials.

For example, an additional barrier film 178 can be disposed between the support member 105 and the second back plate 101b, and the additional barrier film 178 can include an adhesive material, and can be bonded to the support member 105 by a fifth adhesive layer 172e. The additional barrier film 178 can serve as a buffering or cushioning element to buffer or cushion vibrations, impact and the like. However, the present disclosure is not limited thereto, and the additional barrier film 178 may not be disposed.

The micro-coating layer 160 can be disposed in an upper portion of the bending area BA of the display panel 110. The micro-coating layer 160 can be disposed to cover one side of the barrier film 173.

Since tensile force is applied to the lines 140 disposed on the display panel 110 when the display panel 110 is bent to thereby occur fine cracks in the lines, the micro-coating layer 160 can serve to protect the lines 140 by coating resin with a small thickness at a bending position. That is, the micro-coating layer 160 is comprised of resin, and is applied to the lines 140 to reinforce the lines 140 against cracks.

The micro-coating layer 160 can adjust the neutral plane of the bending area BA. For example, the neutral plane can mean a virtual surface that is not stressed because compressive force and tensile force applied to structures cancel each other out when the structures are bent. When two or more structures are stacked, a virtual neutral plane can be formed between the structures. When the entirety of the structures is bent in one direction, the structures disposed in the bending direction with respect to the neutral plane are compressed by bending, and thus, are subjected to compressive force. On the contrary, the structures disposed in a direction opposite to the bending direction with respect to the neutral plane are stretched by bending and thus, are subjected to tensile force. In general, since the structures are more vulnerable when they are subjected to tensile force among the same levels of compressive force and tensile force, the probability of crack occurrence is higher when they are subjected to tensile force.

The substrate disposed below the neutral plane is compressed and thus, subjected to compressive force. The lines 140 disposed above the neutral plane can be subjected to tensile force and due to the tensile force, cracks can occur in the lines 140. Therefore, to minimize the tensile force to be received by the lines 140, the neutral plane can be positioned above the lines.

By disposing the micro-coating layer 160 on the bending area BA, the neutral plane can be raised upwardly and the neutral plane is formed at a position the same as that of the lines 140 or the lines 140 are located at a position higher than that of the neutral plane. Thus, the lines 140 are not stressed or are subjected to compressive force during bending, whereby the occurrence of cracks can be suppressed.

If the thickness of the micro-coating layer 160 is too thick, an overall thickness of the flexible display device increases, thus, hindering thinning of the flexible display device. If the thickness of the micro-coating layer 160 is too thin, the neutral plane is not optimized and it can be difficult to implement sufficient adhesive force, so the thickness can be 70 μm to 130 μm.

The micro-coating layer 160 can be formed of resin, and can be formed of an acrylic material or urethane acrylate, but the present disclosure is not limited thereto.

As described above, the driving signals supplied through the circuit element (e.g., 161), for example, a gate signal and a data signal can be supplied to the gate lines and the data lines of the active area AA through the lines 140 such as routing lines.

For example, the lines 140 can include a plurality of first lines 141 for transferring data signals to data lines and a plurality of second lines 142 for transferring gate signals to a GIP circuit. However, the present disclosure is not limited thereto.

In the non-active area NA including the bending area BA, for example, the plurality of first lines 141 can be disposed in a central portion thereof and the plurality of second lines 142 can be disposed at edges thereof. That is, the plurality of second lines 142 can be disposed laterally outwardly from the plurality of first lines 141.

For example, the reflective layer 150 can be disposed under the lines 140 in the non-active area NA between the active area AA and the bending area BA.

The reflective layer 150 can be disposed in a whole electrode shape (or an integral shape of electrode) across the entirety of the lines 140 disposed in the non-active area NA between the active area AA and the bending area BA. For example, the reflective layer 150 can be disposed across the entirety of the first lines 141 and the second lines 142, but is not limited thereto. For example, in a plan view of the flexible display device, the reflective layer 150 can be disposed between the lines 140 along the length of the lines 140 in a shape of islands, that is to say the reflective layer 150 may be disposed as a series of islands between each line 140. That is, the reflective layer 150 can be disposed on all of the lines 140 (the first lines 141 and the second lines 142), but can cover only a portion of a length of the lines 140, since the lines 140 extend past between the non-active area NA and the active area AA.

For example, the reflective layer 150 can be disposed on the first flat portion of the display panel 110 between the active area AA and the bending area BA.

For example, the reflective layer 150 can be disposed under the lines 140 in the first flat portion of the display panel 110 between the active area AA and the bending area BA.

For example, the reflective layer 150 can be disposed between the substrate 111 and the first planarization layer 115c on the first flat portion of the display panel 110, but is not limited thereto.

Meanwhile, in an embodiment of the present disclosure, the outer sealing part 185 can be disposed at an edge of the flexible display device as an outer frame.

For example, the outer sealing part 185 can be formed of an epoxy mold, but is not limited thereto. For example, the outer sealing part 185 can be formed of a UV curable material, and can be formed of a UV curable material such as epoxy acrylate, urethane acrylate, polyester acrylate, urethane, urethane acrylate, or silicone acrylate, in which a UV curable oligomer is added. However, the present disclosure is not limited thereto.

For example, the outer sealing part 185 can be disposed in a frame shape along the four edges of the flexible display device. That is, the outer sealing part 185 can surround all of the edges of the flexible display device.

For example, the outer sealing part 185 can be disposed on the lower edge of the cover glass 175 to cover the display panel 110 that is bent (e.g., curved) and the adhesive layer 177 that is exposed and the micro-coating layer 160.

In addition, the inner sealing part 180 can fill an inner space (e.g., interior space) of the bent display panel 110.

For example, the inner sealing part 180 can be formed of an epoxy mold, but is not limited thereto. For example, the inner sealing part 180 can be formed of a UV curable material, and can be formed of a UV curable material such as epoxy acrylate, urethane acrylate, polyester acrylate, urethane, urethane acrylate, or silicone acrylate, in which a UV curable oligomer is added. However, the present disclosure is not limited thereto.

For example, the inner sealing part 180 can be disposed on an edge of one side of the flexible display device in which the display panel 110 is bent.

The inner sealing part 180 can be completely cured by the reflective layer 150 during UV curing.

Meanwhile, as described above, in a plan view of the flexible display device, the reflective layer according to an embodiment of the present disclosure can be disposed between the lines in a shape of islands along the lines, which will be described in detail with reference to the drawings.

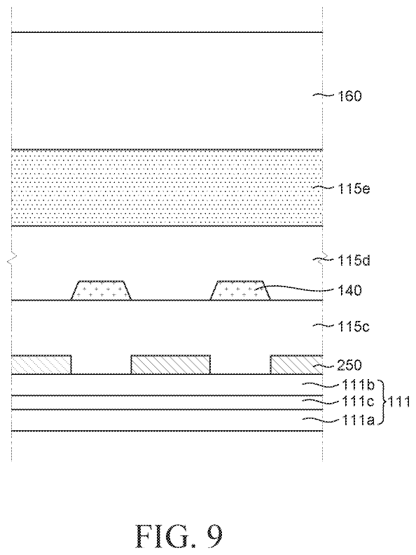

FIG. 9 is a view illustrating a portion of a cross-section of a flexible display device according to another embodiment of the present disclosure as an example.

Other configurations of the flexible display device of another embodiment of the present disclosure of FIG. 9 are substantially identical to those of the flexible display device of an embodiment of the present disclosure of FIGS. 3 to 8 described above except for a difference in terms of a configuration of a reflective layer 250. Therefore, redundant explanations will be omitted.

As in FIG. 6B described above, FIG. 9 illustrates a cross-sectional structure of the non-active area between the active area and the bending area in detail.

Referring to FIG. 9, a gate signal and a data signal can be transferred from the outside to a pixel disposed in the active area through the lines 140 disposed in the non-active area of the flexible display device, so that light can be emitted.

The first planarization layer 115c can be disposed on the substrate 111.

In addition, the lines 140 can be disposed on the first planarization layer 115c.

In addition, the second planarization layer 115d can be disposed on the lines 140.

The bank 115e and/or the micro-coating layer 160 can be disposed on the second planarization layer 115d.

In another embodiment of the present disclosure, for example, the reflective layer 250 can be disposed under the lines 140 in the non-active area between the active area and the bending area.

In another embodiment of the present disclosure, for example, the reflective layer 250 can be disposed along the lines 140 between the lines 140 in a shape of islands. For example, in a plan view of the flexible display device, the reflective layer 250 can be disposed not to overlap the lines 140 so as not to generate parasitic capacitance, but is not limited thereto.

For example, the reflective layer 250 can be disposed on a flat portion of the non-active area between the active area and the bending area.

For example, the reflective layer 250 can be disposed under the lines 140 in the substrate 111 in the non-active area between the active area and the bending area. For example, the reflective layer 250 can be disposed between the substrate 111 and the first planarization layer 115c, but is not limited thereto.

For example, the reflective layer 250 can be disposed the front of the bending area in the non-active area between the active area and the bending area, but is not limited thereto. A method for manufacturing the flexible display device 100 according to yet another exemplary embodiment of the present disclosure will be further described below.

As shown in FIG. 3, the flexible display device 100 includes a display panel 110. The display panel 100 includes an active area AA and a non-active area NA. The non-active area NA includes a bending area BA. The bending area BA is formed by bending a portion of the non-active area NA in a bending direction. A plurality of light emitting elements 130 are disposed in the active area AA of the display panel 110.

The method for manufacturing the flexible display device 100 according to an exemplary embodiment of the present disclosure includes forming a plurality of lines 140 in the non-active area NA of the display panel 110 to be extent to the active area AA, and forming a reflective layer under the plurality of lines 140 in the non-active area NA between the active area AA and the curved area BA, such as the reflective layer 150 shown in FIGS. 4-5 or the reflective layer 250 shown in FIG. 9.

The embodiments of the present disclosure can also be described as follows:

According to an aspect of the present disclosure, there is provided a flexible display device. The flexible display device includes a display panel including an active area and a non-active area, the non-active area including a bending area, a plurality of light emitting elements disposed in the active area of the display panel, a plurality of lines disposed in the non-active area of the display panel and extending to the active area and a reflective layer disposed under the plurality of lines in the non-active area between the active area and the bending area.

The flexible display device can further include a planarization layer disposed over the plurality of lines and a micro-coating layer disposed on the planarization layer in the bending area.

The reflective layer can be disposed across an entirety of the plurality of lines.

In a plan view of the flexible display device, the reflective layer can be disposed between the plurality of lines along the plurality of lines.

The display panel can include a first flat portion, a second flat portion, and a curved portion between the first flat portion and the second flat portion.

The first flat portion can correspond to the active area and a portion of the non-active area and maintains a flat state, the second flat portion can correspond to another portion of the non-active area, faces the first flat portion, and maintains a flat state, and the curved portion can correspond to the bending area and maintains a bent state with a predetermined curvature.

The reflective layer can be disposed on the first flat portion of the display panel between the active area and the bending area.

The flexible display device can further include a cover glass disposed on an upper portion of the display panel.

The flexible display device can further include an outer sealing part disposed on a lower edge of the cover glass to cover the display panel.

The outer sealing part can be disposed in a frame shape at an edge of the display panel.

The outer sealing part can be disposed on the lower edge of the cover glass to cover the display panel that is bent and the micro-coating layer that is exposed.

The flexible display device can further include an inner sealing part filling an inner space of the bent display panel.

The inner sealing part can be disposed on an edge of one side of the flexible display device in which the display panel is bent.

The bending area may be formed by bending a portion of the non-active area in a bending direction, and at least a portion of the line may be disposed to extend in a diagonal direction at least in the bending area, with the diagonal direction being different from the bending direction.

The thickness of the micro-coating layer at a bending position of the bending area may be less than its thickness at other position.

Although the embodiments of the present disclosure have been described in detail with reference to the accompanying drawings, the present disclosure is not limited thereto and can be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A flexible display device, comprising:
a display panel including:
an active area;
a non-active area, the non-active area including a bending area; and
a plurality of light emitting elements disposed in the active area of the display panel;
a plurality of conductive lines disposed in the non-active area of the display panel and extending to the active area; and
a reflective layer disposed under the plurality of conductive lines in the non-active area between the active area and the bending area.

2. The flexible display device of claim 1, further comprising:
a planarization layer disposed on the plurality of conductive lines; and
a micro-coating layer disposed on the planarization layer in the bending area.

3. The flexible display device of claim 1, wherein the reflective layer is disposed on an entirety of the plurality of conductive lines.

4. The flexible display device of claim 1, wherein in a plan view of the flexible display device, the reflective layer is disposed on an entirety of the non-active area.

5. The flexible display device of claim 1, wherein the display panel further includes a first flat portion, a second flat portion, and a curved portion between the first flat portion and the second flat portion.

6. The flexible display device of claim 5, wherein the first flat portion corresponds to the active area and a first portion of the non-active area and maintains a flat state,
wherein the second flat portion corresponds to a second portion of the non-active area different from the first portion of the non-active area, and faces the first flat portion, and
wherein the curved portion corresponds to the bending area and maintains a bent state with a predetermined curvature.

7. The flexible display device of claim 5, wherein the reflective layer is disposed on the first flat portion of the display panel between the active area and the bending area.

8. The flexible display device of claim 2, further comprising:
a cover glass disposed on an upper portion of the display panel.

9. The flexible display device of claim 8, further comprising:
an outer sealing part disposed on a lower edge of the cover glass and covering an outer surface of the bending area.

10. The flexible display device of claim 9, further comprising a light blocking layer disposed on the lower edge of the cover glass.

11. The flexible display device of claim 9, wherein the outer sealing part covers the micro-coating layer that is exposed.

12. The flexible display device of claim 11, further comprising:
an inner sealing part filling an inner space of the bent display panel and disposed at an inner surface of the bending area.

13. The flexible display device of claim 12, wherein the inner sealing part is disposed on an edge of one side of the flexible display device in which the display panel is bent.

14. A flexible display device, comprising:
a display panel including:
an active area;
a non-active area including a bending area having a curved shape;
a plurality of conductive lines extending in the bending area; and
a plurality of sub-pixels disposed in the active area; and
a circuit element including terminals connected to the display panel by the plurality of conductive lines.

15. The flexible display device of claim 14, wherein the plurality of conductive lines comprise metal nano wire, metal mesh, or carbon nanotube (CNT).

16. The flexible display device of claim 14, wherein each of the plurality of conductive lines is formed in one of a trapezoidal wave shape, a triangular wave shape, a sawtooth wave shape, a sinusoidal wave shape, an omega (Ω) shape, or a rhombus shape.

17. The flexible display device of claim 14, further comprising:
a cover glass; and
an outer sealing part disposed on the cover glass and covering an outer surface of the bending area.

18. The flexible display device of claim 17, further comprising an inner sealing part sealing an inner surface of the bending area, the inner surface of the bending area being opposite to the outer surface of the bending area.

19. The flexible display device of claim 14, wherein the display panel further includes:
a thin film transistor; and
planarization layers disposed on the thin film transistor.

20. The flexible display device of claim 19, wherein the display panel further includes:
a light emitting element; and
an intermediate electrode connecting the thin film transistor to the light emitting element, the intermediate electrode being disposed on one of the planarization layers.
